(19) United States
(12) Patent Application Publication
(10) Pub. No.: US 2013/0122703 A1
(43) Pub. Date: May 16, 2013

(54) METHOD FOR FABRICATING SEMICONDUCTOR DEVICE

(71) Applicant: Mi-Na KU, Gyeonggi-do (KR)

(72) Inventor: Mi-Na KU, Gyeonggi-do (KR)

(21) Appl. No.: 13/340,136

(22) Filed: Dec. 29, 2011

(30) Foreign Application Priority Data
Nov. 10, 2011 (KR) 10-2011-0117029

(51) Int. Cl. H01L 21/768

(52) U.S. Cl. 438/669; 438/674; 257/E21.585; 257/E21.582

(57) ABSTRACT

A method for fabricating a semiconductor device includes forming an etch target layer including an insulation layer and a metal layer over a substrate, forming a hard mask layer pattern over the etch target layer, forming a protective layer pattern which includes a region having a shape of an overhang formed in an upper portion of the hard mask layer pattern, etching the insulation layer of the etch target layer by using the first region as an etch barrier, and etching the metal layer of the etch target layer by using the second region as an etch barrier.

### CROSS-REFERENCE TO RELATED APPLICATIONS

The present application claims priority of Korean Patent Application No. 10-2011-0117029, filed on Nov. 10, 2011, which is incorporated herein by reference in its entirety.

### BACKGROUND

1. Field

Exemplary embodiments of the present invention relate to a semiconductor technology, and more particularly, to a method for fabricating a semiconductor device based on Spacer Patterning Technology.

2. Description of the Related Art

As semiconductor design rule for semiconductor devices decreases, the minimum pitch of a pattern required for forming a semiconductor device also greatly decreases. However, the current resolution of the lithography process used to implement a pattern may not keep up with the decrease in the design rule.

In particular, an excimer laser having the wavelength of approximately 153 nm or an extreme ultraviolet (EUV)-class lithography technology having a shorter wavelength may be used to form patterns of approximately 30 nm or less but is still under development to thereby hardly apply to the actual formation of a pattern at present. To address to the concern, a method of forming fine pattern having a pitch of under the resolution limit based on Spacer Patterning Technology (SPT) has been introduced.

When bit lines are formed based on the SPT scheme, an oxide layer is formed over a substrate and then a metal layer for forming bit lines, such as a tungsten (W) layer, is formed by patterning the oxide layer. Also, a hard mask layer of a dual structure including a first hard mask layer formed of an oxide layer and a second hard mask layer formed of a carbon layer is used to perform a patterning process onto the tungsten (W) layer.

When the oxide layer and the tungsten (W) layer are etched by using the hard mask layer of the dual structure, the oxide layer is etched first by using the second hard mask layer of the carbon layer as an etch barrier, and then the tungsten (W) layer is etched by using the first hard mask layer of the oxide layer.

When the oxide layer is etched using the second hard mask layer, both sides of the first hard mask layer formed of the same oxide layer may not be protected and thus they may not function as a hard mask in the subsequent etch process. Therefore, as shown in FIG. 1, when the tungsten layer 11, which is an etch target layer, over the substrate 10 is etched by using the first hard mask layer 12 as an etch barrier, the tungsten layer 11 may not completely etched enough to be isolated.

To address to the concern, the height of the hard mask layer having the dual structure has to be increased. However, since the increased film height may be vulnerable to film lifting in a stack structure employing the Spacer Patterning Technology (SPT), increasing the height of the hard mask layer may not be appropriate.

As devices are highly integrated and patterns become finer and finer, margins among etched materials may decreased in forming of patterns of approximately 30 nm or less to thereby increase errors in fabricating of semiconductor devices

### SUMMARY

An exemplary embodiment of the present invention is directed to a method for fabricating a semiconductor device that is capable of providing increased selectivity of a hard mask in etching tungsten, when bit lines of approximately 30 nm are formed.

In accordance with an exemplary embodiment of the present invention, a method for fabricating a semiconductor device includes forming an etch target layer including an insulation layer and a metal layer over a substrate, forming a hard mask layer pattern over the etch target layer, forming a protective layer pattern which includes a first region having a shape of an overhang formed in an upper portion of the hard mask layer pattern, and a second region formed on a side of the hard mask layer pattern, etching the insulation layer of the etch target layer by using the first region as an etch barrier, and etching the metal layer of the etch target layer by using the second region as an etch barrier.

In accordance with another exemplary embodiment of the present invention, a method for fabricating a semiconductor device includes forming an etch target layer including an insulation layer and a metal layer over a substrate; forming a hard mask layer pattern over the etch target layer; forming a protective layer pattern which includes a region having a shape of an overhang formed in an upper portion of the hard mask layer pattern; and etching the insulation layer of the etch target layer by using the region as an etch barrier.

### BRIEF DESCRIPTION OF THE DRAWINGS

FIG. 1 is a cross-sectional view illustrating a conventional semiconductor device.

FIGS. 2A to 2G are cross-sectional views illustrating a method for forming bit lines of a semiconductor device based on Spacer Patterning Technology (SPT) in accordance with an exemplary embodiment of the present invention.

FIGS. 3A to 3D are plan views of the semiconductor device obtained after the processes shown in FIGS. 2A, 2C, 2E and 2F, respectively.

FIGS. 4A and 4B are photographs of the cross-sections of the semiconductor device obtained after the processes shown in FIGS. 2E and 2F in accordance with the exemplary embodiment of the present invention.

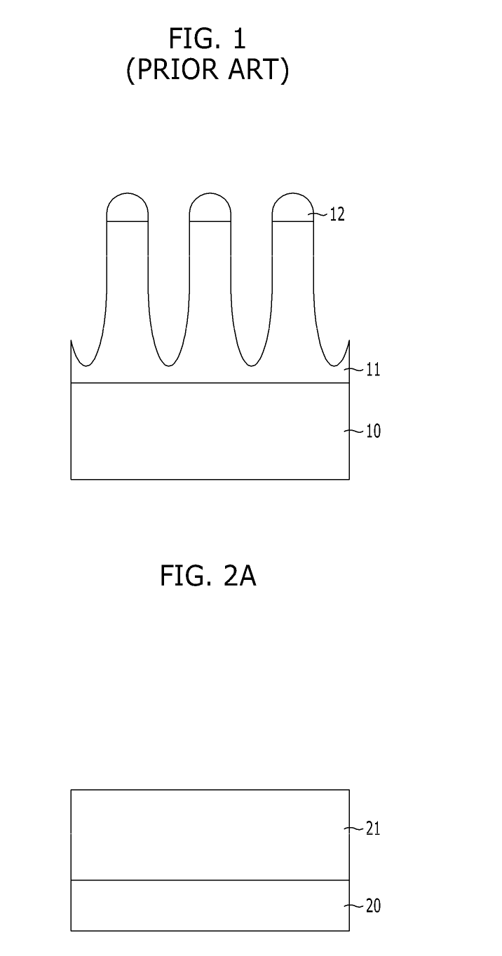

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

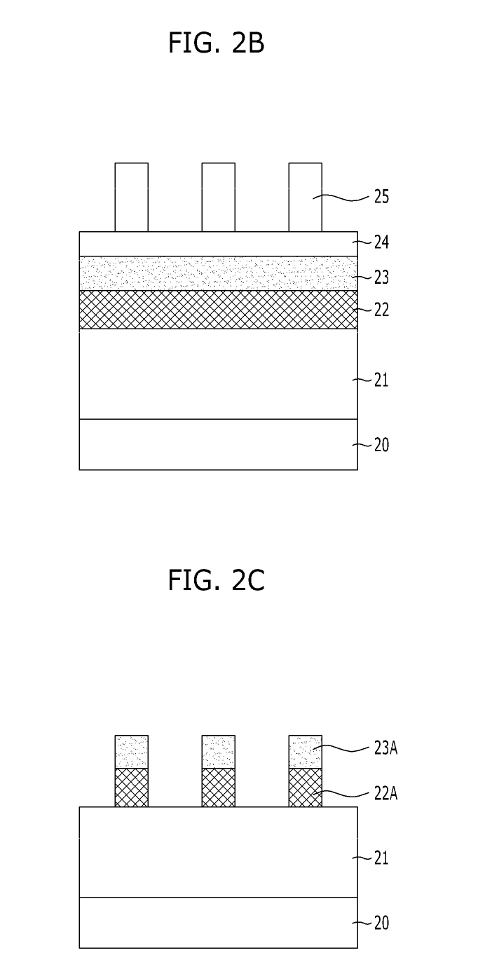

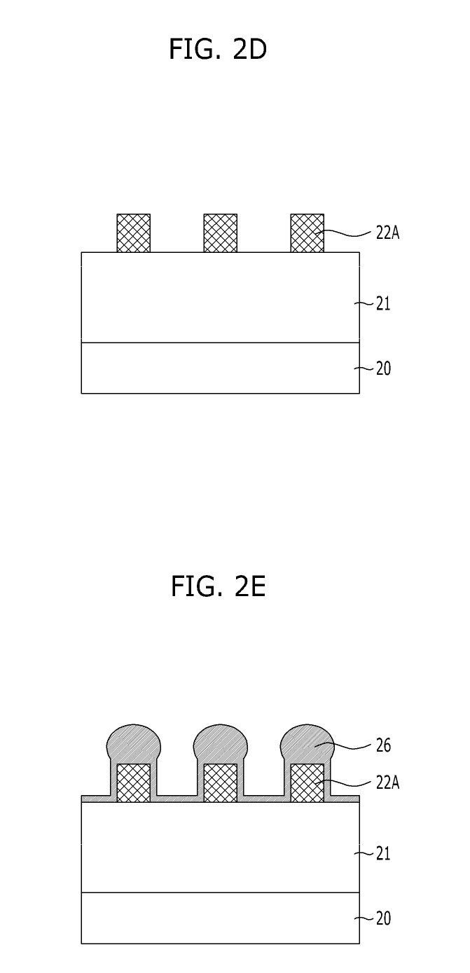

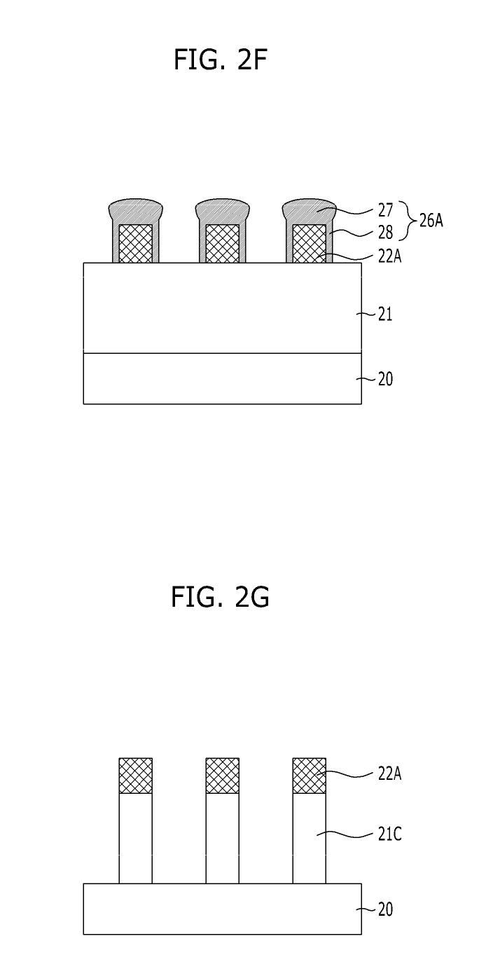

FIGS. 2A to 2G are cross-sectional views illustrating a method for forming bit lines of a semiconductor device based on Spacer Patterning Technology (SPT) in accordance with an exemplary embodiment of the present invention.

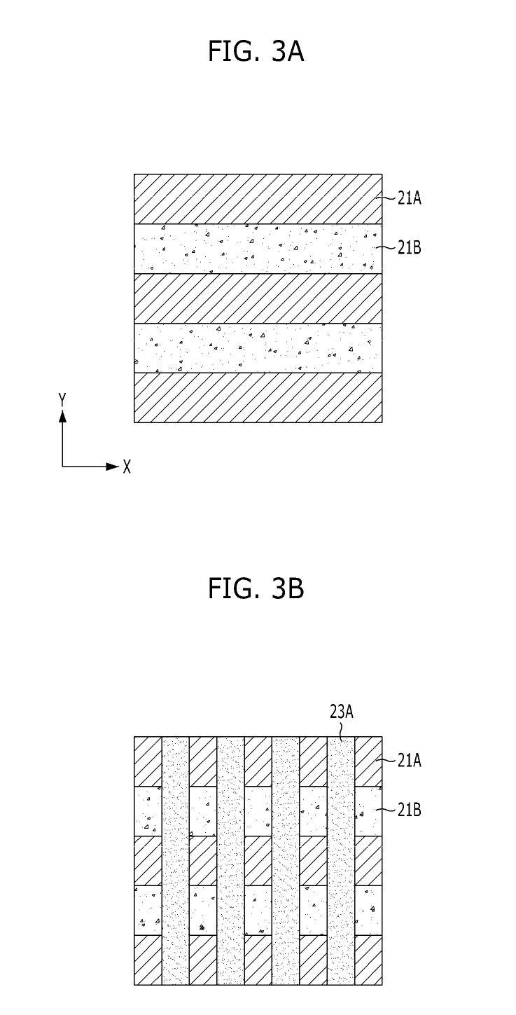

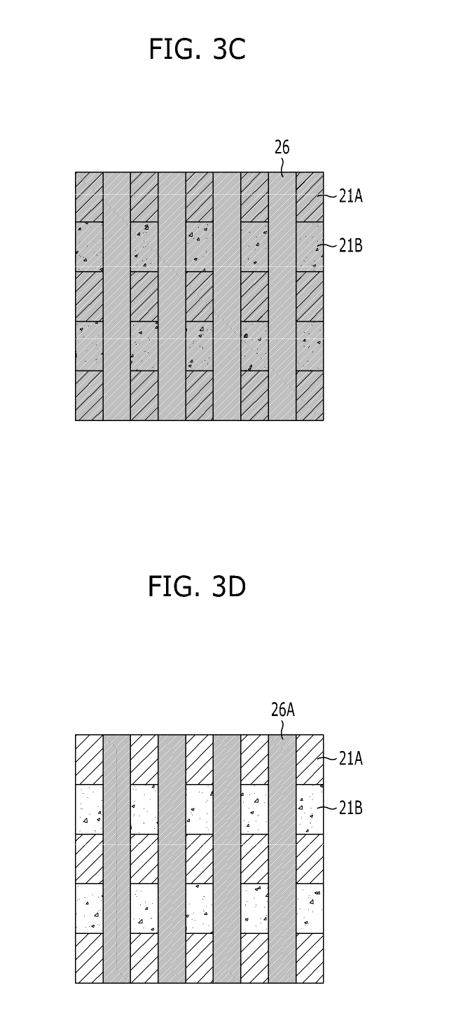

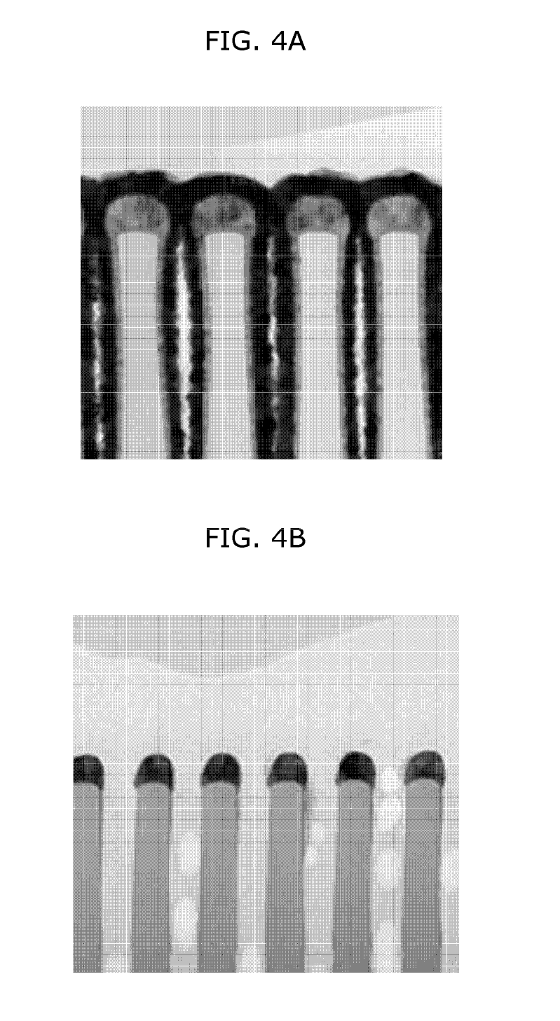

FIGS. 3A to 3D are plan views of the semiconductor device obtained after the processes shown in FIGS. 2A, 2C, 2E and 2F, respectively. FIGS. 4A and 4B are photographs of the cross-sections of the semiconductor device obtained after the processes shown in FIGS. 2E and 2F in accordance with the exemplary embodiment of the present invention.

Referring to FIG. 2A, an etch target layer 21 is formed over a substrate 20.

Herein, as illustrated in FIG. 3A, the etch target layer 21 is formed by depositing an oxide layer 21A, which is a Storage Node Contact (SNC) isolation layer and insulation layer, over the substrate 20, forming line-type storage node contacts in an X-axial direction, and then filling them with a bit line-forming tungsten layer 21B.

Referring to FIG. 2B, a first hard mask layer 22, a second hard mask layer 23, and an anti-reflection layer 24 are sequentially formed over the etch target layer 21. Subsequently, a photoresist layer pattern 25 is formed over the anti-reflection layer 24. Herein, the first hard mask layer 22 may be formed of, for example, a carbon layer, and the second hard mask layer 23 may be formed of, for example, an oxide layer. Also, the anti-reflection layer 24 may be formed of a silicon oxynitride (SiON) layer.

Subsequently, referring to FIG. 2C, a second hard mask layer pattern 23A is formed by using the photoresist layer pattern 25 as an etch barrier and etching the anti-reflection layer 24 and the second hard mask layer 23. A first hard mask layer pattern 22A is then formed by using the second hard mask layer pattern 23A as an etch barrier and etching the first hard mask layer 22. The photoresist layer pattern 25 and the anti-reflection layer 24 may be all removed at a moment when the second hard mask layer pattern 23A is formed.

Herein, as shown in FIG. 3B, the first hard mask layer pattern 22A and the second hard mask layer pattern 23A may be formed by using the photoresist layer pattern 25 in an area other than the area to be filled with the bit line-forming tungsten layer 21B in a Y-axial direction.

Subsequently, as illustrated in FIG. 2D, after the photoresist layer pattern 25 and the anti-reflection layer 24 are all removed, the second hard mask layer pattern 23A remaining over the first hard mask layer pattern 22A is stripped by using, for example, oxygen (O₂).

Subsequently, as illustrated in FIG. 2E, a protective layer 26 is formed over the resultant substrate. Herein, FIG. 3C shows that the protective layer 26 is formed over the resultant substrate along the profile of the etch target layer 21 and the first hard mask layer pattern 22A through, for example, a Physical Vapor Deposition (PVD) process which forms poor step coverage and forms an overhang in the upper portion. Preferably, the protective layer 26 may be formed to have a step coverage ratio of the side of the first hard mask layer pattern 22A to the top of the first hard mask layer pattern 22A of more than approximately 1:4. Also, the protective layer 26 may be formed of, for example, a titanium nitride (TiN) layer.

Subsequently, referring to FIG. 2F, a protective layer pattern 26A is formed by etching a portion of the protective layer 26. Herein, the etch process is performed in such a manner that the overhang region of the protective layer 26 over the first hard mask layer pattern 22A and the protective layer 26 over the etch target layer 21 are etched and the protective layer 26 formed on the side of the first hard mask layer pattern 22A is minimized. As can be seen from FIG. 3D, the protective layer pattern 26A is formed along the top and side of the first hard mask layer pattern 22A.

Preferably, the process may be performed in, for example, an Inductively Coupled Plasma (ICP)-type equipment under the pressure condition of approximately 15 mT to approximately 30 mT, the Transformer Coupled Plasma [TCP] condition of approximately 600Ws to approximately 800Ws, and the bias voltage condition of approximately 0Wb to approximately 20Wb by using a gas, which is usually chlorine (Cl₂).

Herein, FIG. 4A is a photograph of a cross-section of the semiconductor device obtained after the process of forming the protective layer 26, and FIG. 4B is a photograph of a cross-section of the semiconductor device obtained after the process of etching the overhang portion of the protective layer 26 and forming the protective layer pattern 26A.

Referring back to FIG. 2F, as a result of the partial etch process, the protective layer pattern 26A is divided into an overhang region 27 formed in the upper portion of the first hard mask layer pattern 22A and a protection region 28 formed on the side of the first hard mask layer pattern 22A. In the subsequent process, the overhang region 27 functions as a hard mask for etching the oxide layer 21A of the etch target layer 21, and the protection region 28 functions as a protective layer for protecting the first hard mask layer pattern 22A.

Subsequently, the oxide layer 21A shown in FIG. 3D of the etch target layer 21, which is an SNC isolation layer, is etched by using the overhang region 27 of the protective layer pattern 26A. Herein, the protection region 28 of the protective layer pattern 26A protects the first hard mask layer pattern 22A to minimize the etching of the first hard mask layer pattern 22A, which is formed of an oxide layer. Preferably, when the oxide layer 21A shown in FIG. 3D is etched by using the overhang region 27 as an etch barrier, usually a C₄F₈ or C₄F₆ gas may be used under the top source power condition of approximately 500Ws to approximately 800Ws and the bias power condition of approximately 200 Vb to approximately 300Vb.

Subsequently, the protective layer pattern 26A is selectively removed through a sulfuric acid and hydroperoxide mixture (SPM) cleaning process using a mixed solution of sulfuric acid (H₂SO₄) and hydroperoxide (H₂O₂).

Subsequently, referring to FIG. 2G, bit lines 21C are formed by using the first hard mask layer pattern 22A as an etch barrier and etching the bit line-forming tungsten layer 21B shown in FIG. 3D of the etch target layer 21. The bit line-forming tungsten layer 21B is deposited in an X-direction perpendicular to a direction (Y— direction) of depositing the hard mask layer pattern 22A. Herein, usually a Cl₂, NF₃, or SiCl₄ gas may be used under the top source power condition of approximately 500Ws to approximately 800Ws and the bias power condition of approximately 100 Vb to approximately 200 Vb.

The first hard mask layer pattern 22A remaining after the above process is removed by using a chemical.

According to the exemplary embodiment of the present invention, when the hard mask for etching the bit line-forming tungsten layer 21B is formed, the selectivity of the hard mask may be increased by depositing the protective layer through a physical vapor deposition (PVD) process based on the step coverage characteristics over the finally patterned hard mask.

According to an exemplary embodiment of the present invention, when bit lines of approximately 30 nm or less are formed, the selectivity of a hard mask in etching tungsten may be increased, and thereby a semiconductor device may be highly integrated and the yield may be improved.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming an etch target layer including an insulation layer and a metal layer over a substrate;
forming a hard mask layer pattern over the etch target layer;
forming a protective layer pattern which includes a first region having a shape of an overhang formed in an upper portion of the hard mask layer pattern, and a second region formed on a side of the hard mask layer pattern;
etching the insulation layer of the etch target layer by using the first region as an etch barrier; and
etching the metal layer of the etch target layer by using the second region as an etch barrier.

2. The method of claim 1, wherein the forming of the protective layer pattern comprises:
depositing a protective layer along a profile of the etch target layer and the hard mask layer pattern; and
forming a protective layer pattern by etching a portion of the protective layer.

3. The method of claim 2, wherein the depositing of the protective layer is performed through a physical vapor deposition (PVD) process wherein the protective layer includes an overhang region in an upper portion of the hard mask pattern.

4. The method of claim 2, wherein the protective layer is formed of a titanium nitride (TiN) layer.

5. The method of claim 2, wherein the forming of the protective layer pattern is performed in an Inductively Coupled Plasma (ICP)-type equipment under a pressure condition of approximately 15 mT to approximately 30 mT, a Transformer Coupled Plasma [TCP] condition of approximately 600Ws to approximately 800Ws, and a bias voltage condition of approximately 0Wb to approximately 20Wb by using a chlorine (Cl₂) gas.

6. The method of claim 1, wherein the protective layer pattern is formed to have a step coverage ratio of a side of the hard mask layer pattern to a top of the hard mask layer pattern of approximately 1:N, where N is a positive integer.

7. The method of claim 6, wherein N is equal to or greater than 4.

8. The method of claim 1, wherein the etching of the insulation layer of the etch target layer is performed by using a C₄F₈ or C₄F₆ gas under a top source power condition of approximately 500Ws to approximately 800Ws and a bias power condition of approximately 200 Vb to approximately 300Vb.

9. The method of claim 1, wherein the etching of the metal layer of the etch target layer is performed by using a Cl₂, NF₃, or SiCl₄ gas under a top source power condition of approximately 500Ws to approximately 800Ws and a bias power condition of approximately 100 Vb to approximately 200 Vb.

10. The method of claim 1, wherein the forming of the etch target layer comprises:
depositing the insulation layer over the substrate;
forming line-type contacts inside the insulation layer in an X-axial direction; and
filling the line-type contacts with the metal layer.

11. The method of claim 1, wherein the insulation layer includes an insulation layer for forming a Storage Node Contact (SNC) isolation layer, and the metal layer includes a metal layer for forming bit lines.

12. The method of claim 1, wherein the insulation layer includes an oxide layer, and the metal layer includes a tungsten layer.

13. The method of claim 1, wherein the insulation layer and the hard mask layer pattern are formed of the same material.

14. The method of claim 1, wherein the forming of the hard mask layer pattern comprises:
sequentially forming a first hard mask layer and a second hard mask layer over the etch target layer;
forming a photoresist layer pattern over the second hard mask layer;
forming a second hard mask layer pattern by using the photoresist layer as an etch barrier and etching the second photoresist layer;
forming a first hard mask layer pattern by using the second hard mask layer pattern as an etch barrier and etching the first hard mask layer;
removing the photoresist layer pattern; and
removing the second hard mask layer pattern to form the first hard mask layer pattern as the hard mask pattern.

15. The method of claim 14, wherein the first hard mask layer includes an oxide layer, and the second hard mask layer includes a carbon layer.

16. The method of claim 14, wherein the second hard mask layer pattern is removed using oxygen (O₂).

17. The method of claim 14, further comprising:
forming an anti-reflection layer over the second hard mask layer.

18. The method of claim 11, further comprising:
selectively removing the protective layer pattern by performing a sulfuric acid and hydroperoxide mixture (SPM) cleaning process using a mixed solution of sulfuric acid and hydroperoxide.

19. A method for fabricating a semiconductor device, comprising:
forming an etch target layer including an insulation layer and a metal layer over a substrate;
forming a hard mask layer pattern over the etch target layer;
forming a protective layer pattern which includes a region having a shape of an overhang formed in an upper portion of the hard mask layer pattern; and
etching the insulation layer of the etch target layer by using the region as an etch barrier.

20. The method of claim 19, wherein the protective layer pattern includes a second region formed on a side of the hard mask layer pattern, and further comprising etching the metal layer of the etch target layer by using the second region as an etch barrier.
